(19) United States
(12) Patent Application Publication
(10) Pub. No.: US 2014/0045336 A1
(43) Pub. Date: Feb. 13, 2014

(54) METHOD OF MANUFACTURING A SEMICONDUCTOR DEVICE

(71) Applicant: SK HYNIX INC., Icheon-si (KR)

(72) Inventor: Chang Ki PARK, Suwon-si (KR)

(73) Assignee: SK HYNIX INC., Icheon-si (KR)

(21) Appl. No.: 13/715,500

(22) Filed: Dec. 14, 2012

(30) Foreign Application Priority Data
Aug. 8, 2012 (KR) 10-2012-0086896

(51) Int. Cl. H01L 21/308

(52) U.S. Cl. CPC H01L 21/308
USPC 438/703

(57) ABSTRACT

A method of manufacturing a semiconductor device having patterns with different widths. The method includes etching a sacrificial pattern using a protective pattern that has a greater width and remains during an etch process of a spacer layer. Since the sacrificial pattern that has a greater width and remains under the protective pattern having a greater width is used as a pad mask pattern, a separate process of forming a pad mask pattern may not be necessary. Therefore, a method of manufacturing a semiconductor device may be simplified.

### CROSS-REFERENCE TO RELATED APPLICATION

The present application claims priority to Korean patent application number 10-2012-0086896 filed on Aug. 8, 2012, in the Korean Intellectual Property Office, which is incorporated by reference herein in its entirety.

### BACKGROUND

1. Technical Field

The present invention relates generally to a method of manufacturing a semiconductor device and, more particularly, to a method of manufacturing a semiconductor device having patterns with different widths.

2. Related Art

Semiconductor devices may include patterns of various sizes. For example, a NAND flash memory device includes gate lines comprised of a source select line, a drain select line and a plurality of word lines interposed therebetween. In general, a word line has a smaller width than a source select line or a drain select line. The source select line is coupled to a gate of a source select transistor, the drain select line is coupled to a gate of a drain select transistor, and the word lines may be coupled to gates of memory cells.

As memory cell size is reduced to achieve a higher degree of integration, various methods have been proposed to form fine word lines by overcoming a resolution limit of exposure equipment. For example, a Spacer Patterning Technology (SPT) process for forming fine word lines has been proposed to overcome a resolution limit of exposure equipment.

### SUMMARY

Accordingly, a need arises for a simplified manufacturing process for semiconductor devices having patterns with different widths. When spacer patterning technology is employed, a width of a word line is defined by a width of a spacer. Spacers are formed through a series of processes, including forming a sacrificial pattern on an etch target layer, forming a spacer layer over a surface of the sacrificial pattern, etching the spacer layer to expose the sacrificial pattern with the spacer layer remaining along a sidewall of the sacrificial pattern, and removing the exposed sacrificial pattern. In this situation, the width of the spacer may be controlled by a deposition thickness of the spacer layer. Therefore, in order to form a drain select line or a source select line having a greater width than a word line, a separate pad mask pattern having a greater width than the spacer may further be formed on the etch target layer. However, the addition of a process for forming the pad mask pattern may increase manufacturing costs. Various embodiments relate to a method of manufacturing a semiconductor device capable of simplifying manufacturing processes.

A method of manufacturing a semiconductor device according to an embodiment of the present invention includes forming a sacrificial layer over an etch target layer, forming a first protective pattern having a first width and a second protective pattern having a second width greater than the first width on the sacrificial layer, forming a first sacrificial pattern under the first protective pattern and a second sacrificial pattern under the second protective pattern by etching the sacrificial layer by using the first and second protective patterns as an etch barrier, forming a spacer layer over an entire surface of a resultant structure after forming the first and second sacrificial patterns, etching the spacer layer to form spacers along sidewalls of the first and second sacrificial patterns, removing the first sacrificial pattern exposed during the etching of the spacer layer by using the second protective pattern remaining during the etching of the spacer layer as an etch barrier, and forming target patterns by etching the etch target layer by using the second sacrificial pattern and the spacers as an etch barrier.

### BRIEF DESCRIPTION OF THE DRAWINGS

The above and other aspects, features and advantages of the present invention will be more clearly understood from the following detailed description taken in conjunction with the accompanying drawings, in which:

FIGS. 1A and 1B are plan views of a semiconductor device according to an embodiment of the present invention;

FIGS. 2A to 2G are cross-sectional views that aid in describing a method of manufacturing a semiconductor device according to an embodiment of the present invention;

FIG. 3 is a block diagram showing the configuration of a memory system according to an embodiment of the present invention; and

FIG. 4 is a block diagram showing the configuration of a computing system according to an embodiment of the present invention.

### DETAILED DESCRIPTION

Hereinafter, various embodiments of the present invention will be described in detail with reference to the accompanying drawings. The present invention may, however, be embodied in different forms and should not be construed as limited to the embodiments set forth herein. Although embodiments in accordance with the present invention are described with reference to a number of examples thereof, it should be understood that numerous variations and modifications can be devised by those skilled in the art that will fall within the spirit and scope of the invention. Like reference numerals refer to like elements throughout the specification and drawings.

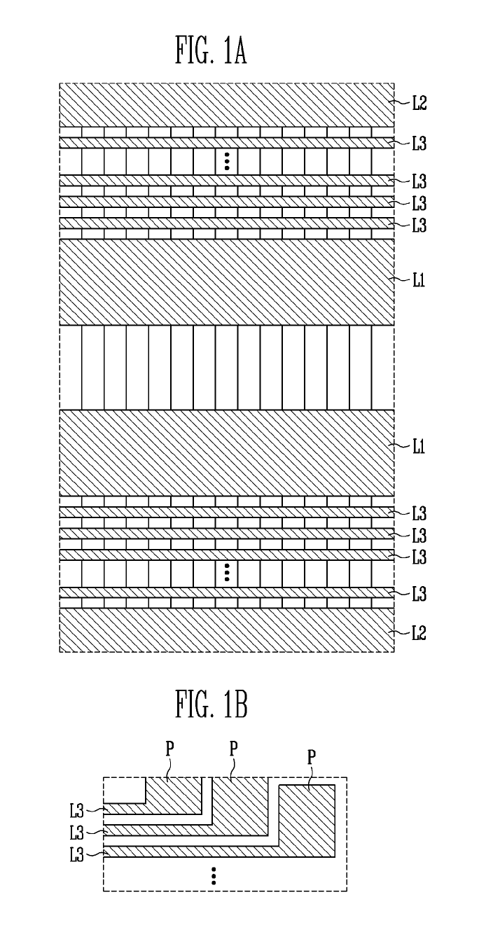

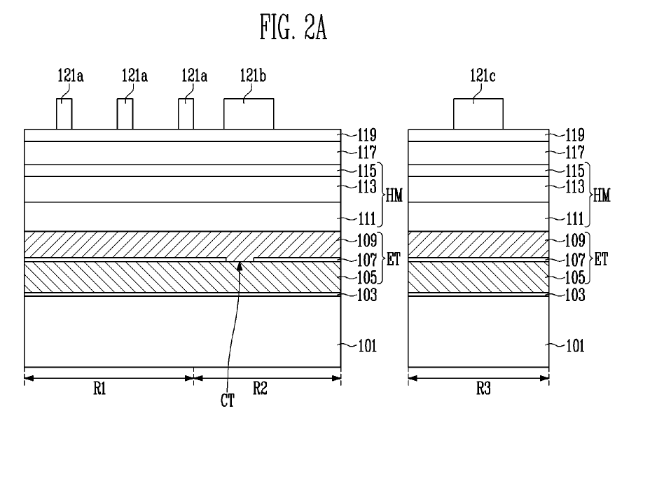

FIG. 1A illustrates a cell region where gate lines of a NAND flash memory device are formed. FIG. 1B illustrates a peripheral region where pad portions coupled to the gate lines of the NAND flash memory device are formed.

Referring now to FIG. 1A, the gate lines of the NAND flash memory device may include selection lines L1 and L2 and word lines L3. These selection lines may include a source selection line L1 and a drain selection line L2. The source selection line L1 may be coupled to a gate of a source select transistor for selecting a cell string, and the drain selection line L2 may be coupled to a gate of a drain select transistor for selecting a cell string. The word lines L3 may be disposed between the source selection line L1 and the drain selection line L2. The word lines L3 may be coupled to gates of memory cells for storing data.

To achieve a greater degree of integration, a width of the word line L3 may be smaller than a width of the source selection line L1 and a width of the drain selection line L2. The width of the word line L3 may be smaller than a resolution limit of exposure equipment. According to an embodiment of the present invention, a gap between the source selection line L1 and the word line L3 may be substantially the same as a gap between the drain selection line L2 and the word line L3.

In FIG. 1B, the gate lines of the NAND flash memory device (for example, the word lines L3) are shown extending to pad portions P in the peripheral region. The pad portions P may be coupled to lines (not illustrated) configured to transfer external signals through a contact structure (not illustrated). In order to ensure an alignment margin between the pad portions P and the contact structure, the width and spacing of the pad portions P may be greater than the width of the gate lines (L3).

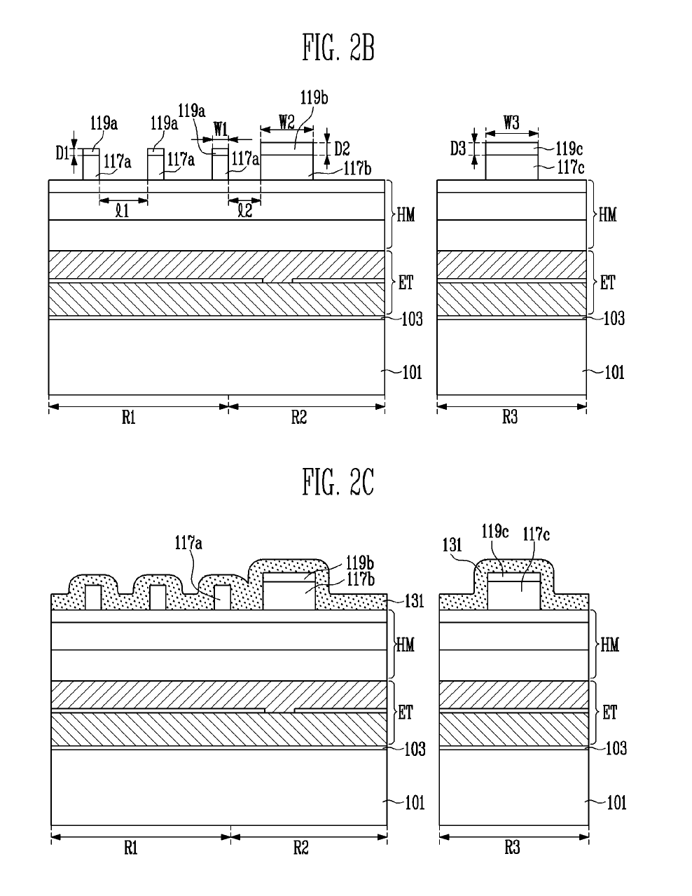

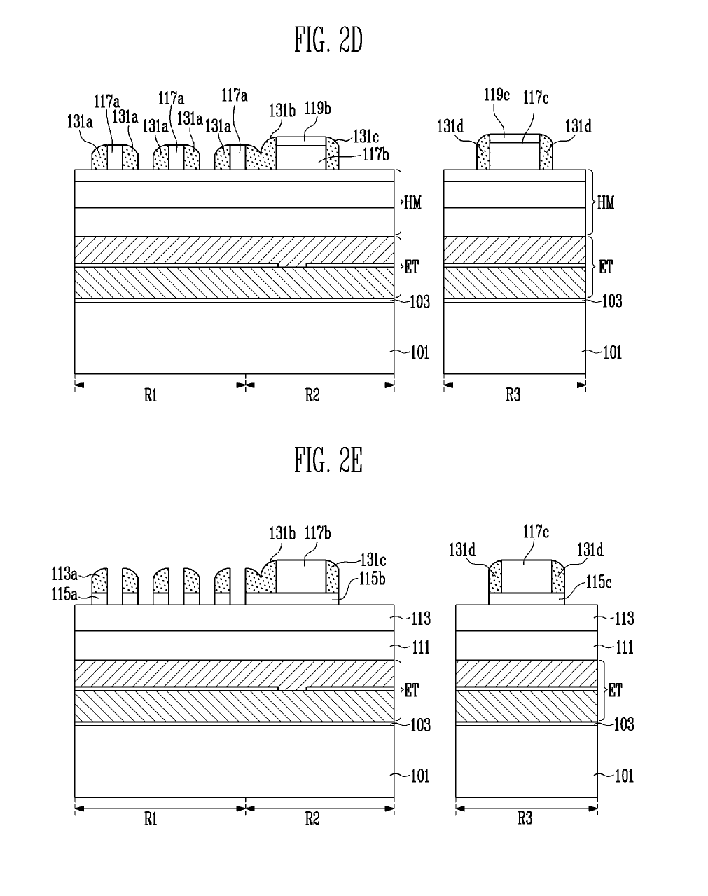

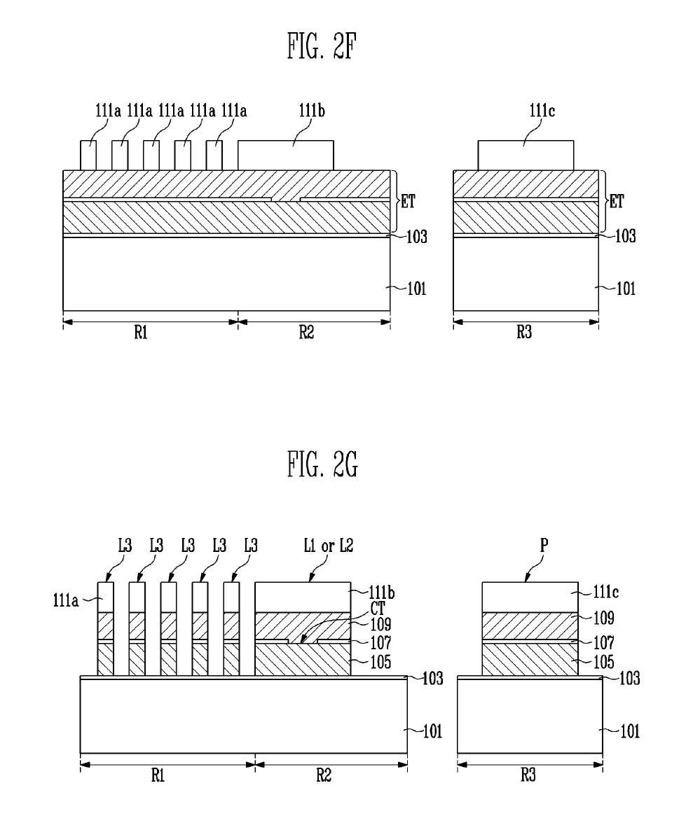

FIGS. 2A to 2G illustrate a cross section taken in a direction crossing the gate lines of FIG. 1A and a cross section of the pad portion.

Referring to FIG. 2A, an etch target layer ET and a sacrificial layer 117 may be formed over a substrate 101 including first to third regions R1 to R3. A mask stacked structure HM may be further formed on the etch target layer ET before the sacrificial layer 117 is formed.

A relatively small pattern, among target patterns to be formed during subsequent processes, may be formed in the first region R1, while a relatively large pattern, among those target patterns, may be formed in the second and third regions R2 and R3. For example, word lines may be formed in the first region R1, a drain selection line or a source selection line may be formed in the second region R2, and a pad portion may be formed in the third region R3.

The etch target layer ET may include material layers forming the target patterns. In order to form a word line, a source selection line, and a drain selection line of a NAND flash memory device as the target patterns, the etch target layer ET may be formed by stacking a first conductive layer 105 configured as a floating gate, a dielectric layer 107 and a second conductive layer 109 configured as a control gate, on top of one another. The dielectric layer 107, where the source selection line and the drain selection line are to be formed, may have a contact hole CT through which the first conductive layer 105 is exposed. The first and second conductive layers 105 and 109 may be electrically connected to each other through the contact hole CT. In addition, before the first conductive layer 105 is formed, a gate insulating layer 103 may be further formed on the substrate 101.

The mask stacked structure HM may include at least one material layer in accordance with an etch selectivity with respect to the etch target layer ET, a spacer layer to be formed during subsequent processes, and the sacrificial layer 117. For example, the mask stacked structure HM may be formed by stacking first to third material layers 111, 113 and 115, on top of one another. The first material layer 111 may be formed of a material with an etch selectivity with respect to the second conductive layer 109 of the etch target layer ET. For example, the first material layer 111 may include an oxide layer. The second material layer 113 may be formed of a material having an etch selectivity with respect to the spacer layer or the first material layer 111. For example, the second material layer 113 may include polysilicon. The third material layer 115 may be formed of a material having an etch selectivity with respect to the spacer layer. For example, the third material layer 113 may be formed of SiON. The mask stacked structure HM may not be formed if a spacer and a sacrificial pattern to be formed through subsequent processes are able to sufficiently function as an etch barrier during patterning of the etch target layer ET.

Various material layers may be used to form the sacrificial layer 117. For example, the sacrificial layer 117 may include organic materials containing carbon. Examples of the organic materials may include a Spin On Coating (SOC) layer, a Spin On Glass (SOG) layer or an amorphous carbon layer.

A protective layer 119 may be formed on the sacrificial layer 117. The protective layer 119 may be formed to protect a sacrificial pattern to be formed during subsequent processes. The protective layer 119 may include an Undoped Silicate glass (USG) oxide layer or an inorganic anti-reflective layer. When the protective layer 119 includes an inorganic anti-reflection layer, diffused reflection of a light source may be prevented during a photolithography process for forming first to third photoresist patterns 121a, 121b and 121c, thereby securing the profile of the first to third photoresist patterns 121a, 121b and 121c. The inorganic anti-reflective layer may be formed of SiON.

The first to third photoresist patterns 121a, 121b and 121c may be formed on the protective layer 119 by using a photolithography process using a single exposure mask. The first photoresist patterns 121a may be disposed in the first region R1, the second photoresist pattern 121b may be formed in the second region R2, and the third photoresist pattern 121c may be formed in the third region R. Each of the second and third photoresist patterns 121b and 121c may have a greater width than the first photoresist pattern 121a. The third photoresist pattern 121c may have the same or greater width than the second photoresist pattern 121b. The first to third photoresist patterns 121a, 121b and 121c may be arranged without any alignment error in accordance with the arrangement of exposed and unexposed areas of the exposure mask.

Referring to FIG. 2B, by using the first to third photoresist patterns 121a, 121b and 121c of FIG. 2A as an etch barrier, areas of the protective layer 119 not covered by the first to third photoresist patterns 121a, 121b and 121c may be removed using an etch process. As a result, a first protective pattern 119a may have a first width W1 defined by the first photoresist pattern 121a, a second protective pattern 119b may have a second width W2 defined by the second photoresist pattern 121b, and a third protective pattern 119c may have a third width W3 defined by the third photoresist pattern 121c.

Each of the second and third widths W2 and W3 may be greater than the first width W1. A first gap l1 between adjacent first protective patterns 119a and a second gap l2 between adjacent first and second protective patterns 119a and 119b may vary depending on the arrangement of the exposed and unexposed areas of the exposure mask used to form the first to third photoresist patterns 121a, 121b and 121c. For example, the first gap l1 may be more than three times as wide as the first width W1, and the second gap l2 may be less than twice the first width W1. Since the arrangement of the first, second and third protective patterns 119a, 119b and 119c is determined by the arrangement of the first to third photoresist patterns 121a, 121b and 121c with no alignment errors, the first, second and third protective patterns 119a, 119b and 119c may be arranged without an alignment error.

Subsequently, areas of the sacrificial layer 117 not covered by the first, second and third protective patterns 119a, 119b and 119c may be removed using an etch process by using the remaining first to third photoresist patterns 121a, 121b and 121c and the remaining first, second and third protective patterns 119a, 119b and 119c as etch barriers. As a result, a first sacrificial pattern 117a may be formed under the first protective pattern 119a, a second sacrificial pattern 117b may be formed under the second protective pattern 119b, and a third sacrificial pattern 117c may be formed under the third protective pattern 119c. Since the arrangement of the first to third sacrificial patterns 117a, 117b and 117c is determined by the first, second and third protective patterns 119a, 119b and 119c with no alignment errors, the first, second and third sacrificial patterns 117a, 117b and 117c may be arranged without any alignment error. The first, second and third photoresist patterns 121a, 121b and 121c may be removed while the protective layer 119 or the sacrificial layer 117 is etched.

The first, second and third protective patterns 119a, 119b and 119c may be reduced in thickness since portions of the first, second and third protective patterns 119a, 119b and 119c are etched during an etch process of the sacrificial layer 117. Here, since the width of each of the second and third protective patterns 119b and 119c is greater than the width of the first protective pattern 119a, and the first, second and third protective patterns 119a, 119b and 119c have different surface areas, loading effects may occur. In other words, during the etch process of the sacrificial layer 117, each of the second and third protective patterns 119b and 119c having larger surface areas may suffer a greater thickness loss than the first protective pattern 119a having a smaller surface area.

While the etch process of the sacrificial layer 117 is being etched, the difference in thickness loss between the first protective pattern 119a and the second and third protective patterns 119b and 119c may be optimized by controlling etching gas, RF power, or a pressure condition. The etch process of the sacrificial layer 117 for forming the first to third sacrificial patterns 117a, 117b and 117c may be performed so that the second and third protective patterns 119b and 119c may be reduced in thickness without being completely removed. Meanwhile, when the first protective pattern 119a remains after the etch process of the sacrificial layer 117, a residual thickness D1 of the first protective pattern 119a may be smaller than a residual thickness D2 of the second protective pattern 119b and a residual thickness D3 of the third protective pattern 119c due to loading effects.

The etch process of the sacrificial layer 117 may be performed using dry etching or wet etching. When the sacrificial layer 117 is etched using dry etching, an isotropic etch process may be performed to maximize loading effects. When the sacrificial layer 117 is etched using the isotropic etch process to maximize loading effects, CF₄ gas with a relatively low carbon content, among gases containing fluorine and carbon, may be used, and bias power of etching equipment may be reduced. When a USG oxide layer is used as the protective layer 119, loading effects may be caused by using wet etching.

Referring to FIG. 2C, the first sacrificial pattern 117a may be exposed by removing the remaining first protective pattern 119a. When the first protective pattern 119a is removed, portions of the second and third protective patterns 119b and 119c may be etched. However, since each of the second and third protective patterns 119b and 119c has a greater thickness than the first protective pattern 119a, the second and third protective patterns 119b and 119c may be reduced in thickness without being completely removed.

Subsequently, a spacer layer 131 may be formed over the entire surface of a resultant structure including the first, second and third sacrificial patterns 117a, 117b and 117c. The spacer layer 131 may include a material layer having an etch selectivity with respect to the sacrificial layer 117. For example, the spacer layer 131 may include an oxide layer.

A deposition thickness of the spacer layer 131 may determine a line width of a target pattern to be formed with a small width. Since the deposition thickness of the spacer layer 131 may be less than a resolution limit of exposure equipment, a narrow line width of the target pattern to be formed may be smaller than the resolution limit of exposure equipment.

The deposition thickness of the spacer layer 131 may be controlled by various methods depending on a narrow line width of a target pattern to be formed. The deposition thickness of the spacer layer 131 may be controlled so as not to fill space between adjacent first sacrificial patterns 117a. In addition, the deposition thickness of the spacer layer 131 may be controlled so that a central space portion between adjacent first sacrificial patterns 117a may be exposed by substantially the same width as the first width W1. In addition, the deposition thickness of the spacer layer 131 may be controlled to the same value as the first width W1. When the second gap l2 is determined to be less than twice the first width W1, and the deposition thickness of the spacer layer 131 is substantially the same as the first width W1 during the processes described above with reference to FIG. 2B, a space between the first and second sacrificial patterns 117a and 117b may be filled with the spacer layer 131.

Referring to FIG. 2D, the spacer layer 131 as illustrated in FIG. 2C may be etched using a blanket etch process, so that the spacer layer 131 may remain as spacers 131a, 131b, 131c and 131d along sidewalls of the first to third sacrificial patterns 117a, 117b and 117c. Although portions of the second and third protective patterns 119b and 119c may be etched while the spacer layer 131 is being etched, the second and third protective patterns 119b and 119c may be reduced in thickness without being completely removed.

When the space between the first and second sacrificial patterns 117a and 117b is filled with the spacer layer 131 during the processes described above with reference to FIG. 2C, the spacer 131b remaining between the first and second sacrificial patterns 117a and 117b after the etch process of the spacer layer 131 may fill space between the first and second sacrificial patterns 117a and 117b. Hereinafter, for illustration purposes, spacers that remain along sidewalls of the first sacrificial pattern 117a not adjacent to the second sacrificial pattern 117b are referred to as a first spacers 131a, a spacer filling the space between the first and second sacrificial patterns 117a and 117b is referred to as a second spacer 131b, a spacer remaining along a sidewall of the second sacrificial pattern 117b not adjacent to the first sacrificial pattern 117a is referred to as a third spacer 131c, and spacers remaining along sidewalls of the third sacrificial pattern 117c are referred to as fourth spacers 131d.

Referring to FIG. 2E, the first sacrificial patterns 117a may be removed. While the first sacrificial patterns 117a are removed, the second and third sacrificial patterns 117b and 117c may be protected by the remaining second and third protective patterns 119b and 119c and may not be removed. Therefore, separate patterns may not be formed to protect the second and third sacrificial patterns 117b and 117 while the first sacrificial pattern 117b is removed.

As the first sacrificial patterns 117a are removed, areas of the third material layer 115 not covered by the first spacers 131a in the first region R1 may be open. In addition, areas of the third material layer 115 not covered by the second sacrificial pattern 117b and the second and third spacers 131b and 131c in the second region R2 may be open. In addition, areas of the third material layer 115 not covered by the third sacrificial pattern 117c and the fourth spacer 131d in the third region R3 may be open.

A target pattern having a narrow width may be formed in an area covered by the first spacer 131a in the first region R1. A target pattern having a greater width may be formed in an area covered by the second sacrificial pattern 117b and the second and third spacers 131b and 131c in the second region R2 or an area covered by the third sacrificial pattern 117c and the fourth spacer 131d in the third region R3. Therefore, a target pattern having a smaller width may be defined by the width of the first spacer 131a, and a target pattern having a greater width may be determined by the sum of the width of the second sacrificial pattern 117b, the width of the second spacer 131b and the width of the third spacer 131c, or the sum of the width of the third sacrificial pattern 117c and widths of two fourth spacers 131d.

As described above, according to an embodiment of the present invention, the second sacrificial pattern 117b and the third sacrificial pattern 117c formed simultaneously with the first sacrificial pattern 117a and the second, third and fourth spacers 131b, 131c and 131d formed simultaneously with the first spacer 131a may define areas where target patterns having a greater width are to be formed. Therefore, a pattern forming process of a semiconductor device may be simplified since a separate pad mask for defining an area where a target pattern having a greater width is to be formed may not be provided.

According to an embodiment of the present invention, since a gap between a target pattern having a greater width and a target pattern of a smaller width is determined by a one-time photolithography process and the deposition thickness of the spacer layer 131, the gap therebetween may be set to a specific design value. When the gap between first and second sacrificial patterns 117a and 117b is filled with the second spacer 131b in the processes described above with reference to FIG. 2B, the gap between the target pattern having a greater width and the target pattern of a smaller width may be substantially the same as the first width W1 of the first sacrificial pattern 117a.

After the first sacrificial pattern 117a is removed, the second and third protective patterns 119b and 119c may remain or be removed. When the mask stacked structure HM is formed on the etch target layer ET, the mask stacked structure HM may be etched using the second sacrificial pattern 117b and the first to fourth spacers 131a, 131b, 131c and 131d as an etch barrier. For example, third material layer patterns 115a and 115b may be formed by etching the third material layer 115 of the mask stacked structure HM. A width of the third material layer pattern 115a formed in the first region R1 may be smaller than a width of each of the third material layer patterns 115b and 115c formed in the second region R2 and the third region R3.

Referring to FIG. 2F, final mask patterns 111a, 111b and 111c may be formed by further etching the first and second material layers 111 and 113 of the mask stacked structure HM. During the etch process of the mask stacked structure HM for forming the mask patterns 111a, 111b and 111c, a separate etch process may be performed to remove the second sacrificial pattern 117b, the first, second, third and fourth spacers 131a, 131b, 131c and 131d, the second material layer 113 and the third material layer patterns 115a, 115b and 115c. Otherwise, the second sacrificial pattern 117b, the first to fourth spacers 131a, 131b, 131c and 131d, the second material layer 113 and the third material layer patterns 115a, 115b and 115c may remain during the etch process of the mask stacked structure HM for forming the mask patterns 111a, 111b and 111c. A width of the mask pattern 111a formed in the first region R1 may be smaller than a width of each of the mask patterns 111b and 111c formed in the second region R2 and the third region R3.

Referring to FIG. 2G, areas of the etch target layer ET not covered by the mask patterns 111a, 111b and 111c may be etched using the mask patterns 111a, 111b and 111c as an etch barrier. As a result, target patterns (L1, L2, L3 and P) having different widths may be formed in the first region R1 and the second and third regions R2 and R3. The target pattern formed in the first region R1 may be a word line L3. The target pattern formed in the second region R2 may be a source selection line L1 or a drain selection line L2. The target pattern formed in the third region R3 may be a pad portion P.

The word line L3 may have a smaller width than the source selection line L1, the drain selection line L2 and the pad portion P. The word line L3, the source selection line L1, the drain selection lines L2 and the pad portion P may be arranged without any alignment error since the arrangement thereof is determined by first and second photoresist patterns formed using a one-time photolithography process and the deposition thickness of the spacer layer 131. In addition, according to an embodiment of the present invention, a gap between the word line L3 and the source selection line L1 or a gap between the word line L3 and the drain selection line L2 may be substantially the same as a gap between adjacent word lines L3.

A process in which the target patterns L1, L2, L3 and P are formed using the mask patterns 111a, 111b and 111c formed by patterning the mask stacked structure HM has been described above. However, when the second and third sacrificial patterns 117b and 117c and the first to fourth spacers 131a to 131d are able to sufficiently function as an etch barrier during the etch process of the etch target layer ET, the etch target layer ET may be etched using the second and third sacrificial patterns 117b and 117c and the first to fourth spacers 131a to 131d as an etch barrier to form the target patterns L1, L2, L3 and P.

Processes for forming a word line, a drain selection line, a source selection line, and a pad portion of a NAND flash memory device have been described in detail above. However, the present invention is not limited thereto and is applicable to a process of forming patterns of various widths in conventional semiconductor devices.

As described above, according to an embodiment of the present invention, since a separate pad mask is not required to define an area where a target pattern having a greater width is to be formed, a method of manufacturing a semiconductor device may be simplified, and manufacturing costs thereof may be reduced. In addition, according to an embodiment of the present invention, since a separate pad mask is not required, changes in the gap between a wider target pattern and a narrower target pattern caused by misalignment of the pad mask may be completely prevented.

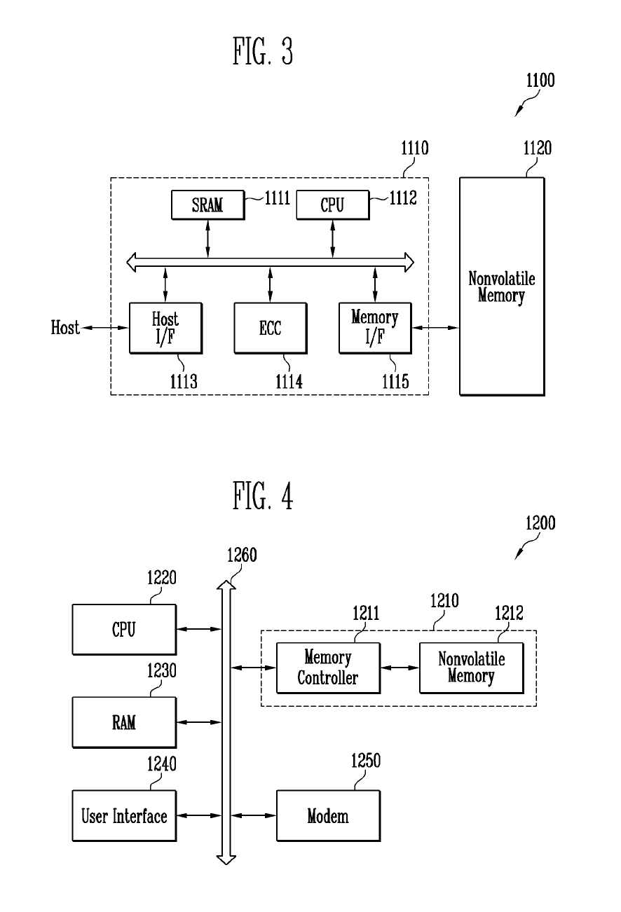

As illustrated in FIG. 3, a memory system 1100 according to an embodiment of the present invention may include a non-volatile memory device 1120 and a memory controller 1110.

The non-volatile memory device 1120 may manufactured by the processes described above in the previous embodiments with reference to FIGS. 1A to 2G. In addition, the non-volatile memory device 1120 may be a multi-chip package composed of a plurality of flash memory chips.

The memory controller 1110 may be configured to control the non-volatile memory device 1120. The memory controller 1110 may include SRAM 1111, a CPU 1112, a host interface 1113, an ECC 1114 and a memory interface 1115. The SRAM 1111 may function as an operation memory of the CPU 1112. The CPU 1112 may perform the general control operation for data exchange of the memory controller 1110. The host interface 1113 may include a data exchange protocol of a host being coupled to the memory system 1100. In addition, the ECC 1114 may detect and correct errors included in a data read from the non-volatile memory device 1120. The memory interface 1115 may interface with the non-volatile memory device 1120.

The memory controller 1110 may further include ROM that stores code data to interface with the host.

The memory system 1100 having the above-described configuration may be a solid state disk (SSD) or a memory card in which the memory device 1120 and the memory controller 1110 are combined. For example, when the memory system 1100 is an SSD, the memory controller 1110 may communicate with the outside (e.g., a host) through one of the interface protocols including USB, MMC, PCI-E, SATA, PATA, SCSI, ESDI and IDE.

As illustrated in FIG. 4, a computing system 1200 according to an embodiment of the present invention may include a CPU 1220, RAM 1230, a user interface 1240, a modem 1250 and a memory system 1210 that are electrically coupled to a system bus 1260. In addition, when the computing system 1200 is a mobile device, a battery may be further included to apply operating voltage to the computing system 1200. The computing system 1200 may further include application chipsets, a Camera Image Processor (CIS) and mobile DRAM.

As described above in connection with FIG. 3, the memory system 1210 may include a non-volatile memory 1212 and a memory controller 1211.

According to an embodiment, a sacrificial pattern is etched using a protective pattern that has a greater width and remains during an etch process of a spacer layer. Since the sacrificial pattern that has a greater width and remains under the protective pattern having a greater width is used as a pad mask pattern, a separate process of forming a pad mask pattern may not be necessary. Therefore, a method of manufacturing a semiconductor device may be simplified.

What is claimed is:

1. A method of manufacturing a semiconductor device, the method comprising:
forming a sacrificial layer over an etch target layer;
forming a first protective pattern having a first width and a second protective pattern having a second width greater than the first width on the sacrificial layer;
forming a first sacrificial pattern under the first protective pattern and a second sacrificial pattern under the second protective pattern by etching the sacrificial layer by using the first and second protective patterns as an etch barrier;
forming a spacer layer over an entire surface of a resultant structure after forming the first and second sacrificial patterns;
etching the spacer layer to form spacers along sidewalls of the first and second sacrificial patterns;
removing the first sacrificial pattern exposed during the etching of the spacer layer by using the second protective pattern remaining during the etching of the spacer layer as an etch barrier; and
forming target patterns by etching the etch target layer by using the second sacrificial pattern and the spacers as an etch barrier.

2. The method of claim 1, wherein the forming of the first and second protective patterns comprises:
forming a protective layer over the sacrificial layer;
forming a first photoresist pattern and a second photoresist pattern having a greater width than the first photoresist pattern on the protective layer by performing a photolithography process using an exposure mask; and
etching the protective layer by using the first and second photoresist patterns as a mask.

3. The method of claim 1, wherein the first and second protective patterns are etched while the sacrificial layer is etched, and the second protective pattern is etched less than the first protective pattern and has a greater thickness than the first protective pattern.

4. The method of claim 1, further comprising removing the first protective pattern before the etching of the spacer layer.

5. The method of claim 1, further comprising:
forming a mask stacked structure on the etch target layer before the forming of the sacrificial layer; and
forming mask patterns by etching the mask stacked structure by using the second sacrificial pattern and the spacers as an etch barrier before the etching of the etch target layer.

6. The method of claim 1, wherein the etching of the spacer layer is performed using an isotropic etch process.

7. The method of claim 6, wherein the isotropic etch process includes a wet etching process.

8. The method of claim 6, wherein the isotropic etch process includes a dry etching process.

9. The method of claim 8, wherein the dry etching process is performed using CF₄ gas.
